(19) United States
(12) Patent Application Publication
(10) Pub. No.: US 2007/0186971 A1
(43) Pub. Date: Aug. 16, 2007

(54) High-efficiency solar cell with insulated vias

(75) Inventors: Darren Lochun, Mountain View, CA (US); James R. Sheats, Palo Alto, CA (US); Gregory A. Miller, Mountain View, CA (US)

Correspondence Address: NANOSOLAR, INC., 2440 EMBARCADERO WAY, PALO ALTO, CA, 94303, US

(73) Assignee: Nanosolar, Inc., Palo Alto, CA (US)

(21) Appl. No.: 11/278,645

(22) Filed: Apr. 4, 2006

Related U.S. Application Data
(63) Continuation-in-part of application No. 11/207,157, filed on Aug. 16, 2005.
Application No. 11/207,157 is a continuation-in-part of application No. 11/039,053, filed on Jan. 20, 2005.
(60) Provisional application No. 60/781,165, filed on Mar. 10, 2006.

(51) Int. Cl. H01L 31/00

(52) U.S. Cl. 136/256

(57) ABSTRACT

Methods and devices are provided for high-efficiency solar cells. In one embodiment, the device comprises of a solar cell having a high efficiency backside electrode configuration, wherein the solar cell comprises of: at least one transparent conductor, a photovoltaic layer, at least one bottom electrode, and at least one backside electrode. The device may include a plurality of electrical conduction fingers mounted to the transparent conductor in the solar cell. The device may include a plurality of filled vias coupled to the electrical conduction fingers, wherein the vias extend through the transparent conductor, the photovoltaic layer, and the bottom electrode, wherein the vias have a conductive core that conducts charge from the transparent conductor to the backside electrode. The via insulating layer may separate the conductive core in each via from the bottom electrode, wherein the insulating layer may be formed by a variety of techniques such as but not limited to aerosol coating of the via.

### CROSS-REFERENCE TO RELATED APPLICATION

This application is a continuation-in-part of commonly-assigned, co-pending U.S. patent application Ser. No. 11/207,157 entitled “OPTOELECTRONIC ARCHITECTURE HAVING COMPOUND CONDUCTING SUBSTRATE” filed Aug. 16,2005 which is a continuation-in-part of commonly-assigned, co-pending U.S. patent application Ser. No. 11/039,053 entitled “SERIES INTERCONNECTED OPTOELECTRONIC DEVICE MODULE ASSEMBLY” filed Jan. 20, 2005. This application also claims the benefit of priority to U.S. Provisional Patent Application Ser. No. 60/781,165 entitled HIGH-EFFICIENCY SOLAR CELL WITH INSULATED VIAS filed on Mar. 10, 2006. The entire disclosures of the above applications are fully incorporated herein by reference for all purposes.

### FIELD OF THE INVENTION

This invention relates to optoelectronic devices and more particularly to mass-manufacture of optoelectronic devices such as solar cells.

### BACKGROUND OF THE INVENTION

Optoelectronic devices can convert radiant energy into electrical energy or vice versa. These devices generally include an active layer sandwiched between two electrodes, sometimes referred to as the front and back electrodes, at least one of which is typically transparent. The active layer typically includes one or more semiconductor materials. In a light-emitting device, e.g., a light-emitting diode (LED), a voltage applied between the two electrodes causes a current to flow through the active layer. The current causes the active layer to emit light. In a photovoltaic device, e.g., a solar cell, the active layer absorbs energy from light and converts this energy to electrical energy exhibited as a voltage and/or current between the two electrodes. Large scale arrays of such solar cells can potentially replace conventional electrical generating plants that rely on the burning of fossil fuels. However, in order for solar cells to provide a cost-effective alternative to conventional electric power generation the cost per watt generated must be competitive with current electric grid rates. Currently, there are a number of technical challenges to attaining this goal.

Most conventional solar cells rely on silicon-based semiconductors. In a typical silicon-based solar cell, a layer of n-type silicon (sometimes referred to as the emitter layer) is deposited on a layer of p-type silicon. Radiation absorbed proximate the junction between the p-type and n-type layers generates electrons and holes. The electrons are collected by an electrode in contact with the n-type layer and the holes are collected by an electrode in contact with the p-type layer. Since light must reach the junction, at least one of the electrodes must be at least partially transparent. Many current solar cell designs use a transparent conductive oxide (TCO) such as indium tin oxide (ITO) as a transparent electrode.

A further problem associated with existing solar fabrication techniques arises from the fact that individual optoelectronic devices produce only a relatively small voltage. Thus, it is often necessary to electrically connect several devices together in series in order to obtain higher voltages in order to take advantage of the efficiencies associated with high voltage, low current operation (e.g. power transmission through a circuit using relatively higher voltage, which reduces resistive losses that would otherwise occur during power transmission through a circuit using relatively higher current).

Several designs have been previously developed to interconnect solar cells into modules. For example, early photovoltaic module manufacturers attempted to use a “shingling” approach to interconnect solar cells, with the bottom of one cell placed on the top edge of the next, similar to the way shingles are laid on a roof. Unfortunately the solder and silicon wafer materials were not compatible. The differing rates of thermal expansion between silicon and solder and the rigidity of the wafers caused premature failure of the solder joints with temperature cycling.

A further problem associated with series interconnection of optoelectronic devices arises from the high electrical resistivity associated with the TCO used in the transparent electrode. The high resistivity restricts the size of the individual cells that are connected in series. To carry the current from one cell to the next the transparent electrode is often augmented with a conductive grid of busses and fingers formed on a TCO layer. However, the fingers and busses produce shadowing that reduces the overall efficiency of the cell. In order for the efficiency losses from resistance and shadowing to be small, the cells must be relatively small. Consequently, a large number of small cells must be connected together, which requires a large number of interconnects and more space between cells. Arrays of large numbers of small cells are relatively difficult and expensive to manufacture. Further, with flexible solar modules, shingling is also disadvantageous in that the interconnection of a large number of shingles is relatively complex, time-consuming and labor-intensive, and therefore costly during the module installation process.

To overcome this, optoelectronic devices have been developed with electrically isolated conductive contacts that pass through the cell from a transparent “front” electrode through the active layer and the “back” electrode to an electrically isolated electrode located beneath the back electrode. U.S. Pat. No. 3,903,427 describes an example of the use of such contacts in silicon-based solar cells. Although this technique does reduce resistive losses and can improve the overall efficiency of solar cell devices, the costs of silicon-based solar cells remains high due to the vacuum processing techniques used in fabricating the cells as well as the expense of thick, single-crystal silicon wafers.

This has led solar cell researchers and manufacturers to develop different types of solar cells that can be fabricated less expensively and on a larger scale than conventional silicon-based solar cells. Examples of such solar cells include cells with active absorber layers comprised of silicon (e.g. for amorphous, micro-crystalline, or polycrystalline silicon cells), organic oligomers or polymers (for organic solar cells), bi-layers or interpenetrating layers or inorganic and organic materials (for hybrid organic/inorganic solar cells), dye-sensitized titania nanoparticles in a liquid or gel-based electrolyte (for Graetzel cells), copper-indium-gallium-selenium (for CIG solar cells), cells whose active layer is comprised of CdSe, CdTe, and combinations of the above, where the active materials are present in any of several forms including but not limited to bulk materials, micro-particles, nano-particles, or quantum dots. Many of these types of cells can be fabricated on flexible substrates (e.g., stainless steel foil). Although these types of active layers can be manufactured in non-vacuum environments, the intra-cell and inter-cell electrical connection typically requires vacuum deposition of one or more metal conducting layers.

For example FIG. 1A illustrates a portion of a prior art solar cell array 1. The array 1 is manufactured on a flexible insulating substrate 2. Series interconnect holes 4 are formed through the substrate 2 and a bottom electrode layer 6 is deposited, e.g., by sputtering, on a front surface of the substrate and on sidewalls of the holes. Current collection holes 8 are then formed through the bottom electrode and substrate at selected locations and one or more semiconductor layers 10 are then deposited over the bottom electrode 6 and the sidewalls of the series interconnect holes 4 and current collection holes 8. A transparent conductor layer 12 is then deposited using a shadow mask that covers the series interconnect holes 4. A second metal layer 14 is then deposited over the backside of the substrate 2 making electrical contact with the transparent conductor layer 12 through the current collection holes and providing series interconnection between cells through the series interconnect holes. Laser scribing 16, 18 on the front side and the back side separates the monolithic device into individual cells.

FIG. 1B depicts another prior art array 20 that is a variation on the array 1. The array 20 is also manufactured on a flexible insulating substrate 22. Series interconnect holes 24 are formed through the substrate 22 and a bottom electrode layer 26 is deposited, e.g., by sputtering, on front and back surfaces of the substrate 22 and on sidewalls of the holes 24. Current collection holes 28 are then formed through the bottom electrode and substrate at selected locations and one or more semiconductor layers 30 and a transparent conducting layer 32 are then deposited over the bottom electrode 26 on the front side and on the sidewalls of the series interconnect holes 24 and current collection holes 28. A second metal layer 34 is then deposited over the backside of the substrate 22 using a shadow mask that covers everything except the current collection holes 28 making electrical contact with the transparent conductor layer 32. Laser scribing 36,38 on the front side and the back side separates the monolithic device into individual cells.

There are two significant drawbacks to manufacturing solar cell arrays as shown in FIGs. 1A-1B. First, the metal layers are deposited by sputtering, which is a vacuum technique. Vacuum techniques are relatively, slow, difficult and expensive to implement in large scale roll-to-roll manufacturing environments. Secondly, the manufacturing process produces a monolithic array and sorting of individual cells for yield is not possible. This means that only a few bad cells can ruin the array and therefore increase cost. In addition, the manufacturing process is very sensitive to the morphology and size of the holes. Since the front to back electrical conduction is along the sidewall of the hole, making the holes larger does not increase conductivity enough. Thus, there is a narrow process window, which can add to the cost of manufacture and reduce yield of usable devices. Furthermore, although vacuum deposition is practical for amorphous silicon semiconductor layers, it is impractical for highly efficient solar cells based, e.g., on combinations of Copper, Indium, Gallium and Selenium or Sulfur, sometimes referred to as CIGS cells. To deposit a CIGS layer, three or four elements must be deposited in a precisely controlled ratio. This is extremely difficult to achieve using vacuum deposition processes.

Thus, there is a need in the art, for an optoelectronic device architecture that overcomes the above disadvantages and a corresponding method to manufacture such cells.

### SUMMARY OF THE INVENTION

Embodiments of the present invention address at least some of the drawbacks set forth above. The present invention provides for the use insulating materials in via holes formed in a photovoltaic device using an improved structure that overcomes the disadvantage of the know devices. At least some of these and other objectives described herein will be met by various embodiments of the present invention.

In one embodiment of the present invention, the device comprises of a solar cell having a high efficiency backside electrode configuration, wherein the solar cell comprises of: at least one transparent conductor, a photovoltaic layer, at least one bottom electrode, and at least one backside electrode. The device may include a plurality of electrical conduction fingers mounted to the transparent conductor in the solar cell. The device may include a plurality of filled vias coupled to the electrical conduction fingers, wherein the vias extend through the at least one transparent conductor, the photovoltaic layer, and the at least one bottom electrode, wherein the vias have a conductive core that conducts charge from the transparent conductor to the backside electrode. The via insulating layer may separate the conductive core in each via from the bottom electrode, wherein the insulating layer is formed by aerosol coating of the via.

It should be understood that the backside conductor may be electrically insulated from the bottom electrode and is connected by the filled vias which are spaced closely enough to each other such that the conductivity requirement of the top electrode is reduced and the need for area obscuring busbars is eliminated. Optionally, the insulating layer may be formed by aerosol coating of the via hole. The insulating layer may be between about 20 to about 100 microns in thickness. The insulating layer may be comprised of at least one of the following materials: ethyl vinyl acetate (EVA), poly vinyl alcohol (PVOH), polyvinyl acetate (PVA), poly vinyl pyrrolidone (PVP), and/or a thermoplastic polymer with a Tg less than about 150° C. The photovoltaic layer may be comprised of at least two discrete layers forming a P-N junction, wherein at least one of the layers comprises of a CIS-based material. Substantially each of the filled vias may each have a diameter of about 1 mm or less. The insulating layer may cover sidewalls of the vias and a portion of the transparent conductor around each of the vias, wherein the portion is within about 2 times the diameter of the via from the edge of the via.

In another embodiment of the present invention, a method is provided comprising of forming a solar cell having a high efficiency backside electrode configuration, wherein the solar cell comprises of: at least one transparent conductor, a photovoltaic layer, and at least one bottom electrode. A plurality of via holes may be formed through the transparent conductor, an photovoltaic layer, and the bottom electrode. The via holes may be coated to form an insulating layer along side wall in each of the holes. The method may include filling each of the via holes with a conductive core that is electrically coupled to the transparent conductor and electrically insulated from the bottom electrode by the insulating layer in the via holes. A backside electrode may be formed and coupled to the conductive core in substantially each of the via holes.

It should be understood that the coating step may be comprised of using a source that sprays insulating material from an underside of the solar cell to avoid substantially covering the transparent conductor with insulating material. Coating may also be comprised of spraying an insulating material from an underside of the solar cell to minimize the amount of material deposited on the transparent conductor without using a mask on the transparent conductor. Coating may be comprised of spraying an insulating material from a top side of the solar cell and using a mask on the transparent conductor to minimize the amount of material deposited on the transparent conductor. Optionally, the coating step may be comprised of spraying a sufficient amount of insulation to coat the via walls without completely filling the via. Coating may also be comprised of spraying a sufficient amount of insulation to coat the via walls and to coat the underside of the bottom electrode to form a bottom insulation layer. Coating may also be comprised of forming an insulating layer by application of aerosol to the via holes.

In another embodiment of the present invention, coating comprises of forming an insulating layer by application of an insulating aerosol comprising of elements of a purely dielectric nature and an adhesive component. Coating may be comprised of using gas impingement on a substantially uniform coating on one side of the solar cell to direct insulating material into each of the via holes. Coating may also be comprised of using gas impingement after spraying of the via holes to clear any via holes occluded by insulating material. Coating may be comprised of forming an insulating layer in each of the vias by printing a substantially uniform coating of an insulating material on one side of the solar cell and using air impingement to direct the insulating material into each of the via holes and creating openings in the uniform coating corresponding to each of the via holes. The method may also include forming the plurality of via holes comprises using a punching device to pierce through the at least one transparent conductor, an photovoltaic layer, and at least one bottom electrode. The method may further include forming a plurality of electrical conduction fingers on the transparent conductor in the solar cell. Coating may also be comprised of forming an insulating layer in each of the vias by printing a substantially uniform coating on one side of the solar cell and using suction on another side of the solar cell to pull insulating material of the uniform coating into each of the via holes and creating openings in the uniform coating corresponding to each of the via holes.

A further understanding of the nature and advantages of the invention will become apparent by reference to the remaining portions of the specification and drawings.

### BRIEF DESCRIPTION OF THE DRAWINGS

FIG. 1A is a cross-sectional schematic diagram of a portion of a solar cell array according to the prior art.

FIG. 1B is a cross-sectional schematic diagram of a portion of an alternative solar cell array according to the prior art.

FIG. 2A is a vertical cross-sectional schematic diagram of a portion of an array of optoelectronic devices according to an embodiment of the present invention.

FIG. 2B is a plan view schematic diagram of the array of FIG. 1A.

FIGS. 2C-2E are plan view schematic diagrams illustrating alternative trace patterns for an optoelectronic device of the type shown in FIGS. 2A-2B.

FIG. 3 is a sequence of schematic diagrams illustrating fabrication of an array of optoelectronic devices according to an embodiment of the present invention.

FIG. 4 is an exploded view schematic diagram illustrating fabrication of an array of optoelectronic devices according to an alternative embodiment of the present invention.

FIG. 5A is an exploded view schematic diagram illustrating fabrication of an array of optoelectronic devices according to another alternative embodiment of the present invention.

FIG. 5B is a cross-sectional schematic diagram illustrating a portion of the array of FIG. 5A.

FIGS. 6A-6I are cross-sectional schematic diagrams illustrating formation of electrical contacts according to embodiments of the present invention.

FIGS. 7-9 show various trace patterns according to embodiments of the present invention.

FIG. 10 shows a via hole forming devices according to embodiments of the present invention.

FIGS. 11A-11D show a method for forming an insulating layer according to embodiments of the present invention.

FIGS. 12A-12C show a method for forming an insulating layer according to embodiments of the present invention.

FIGS. 13A-13C show a method for forming an insulating layer according to embodiments of the present invention.

### DESCRIPTION OF THE SPECIFIC EMBODIMENTS

It is to be understood that both the foregoing general description and the following detailed description are exemplary and explanatory only and are not restrictive of the invention, as claimed. It may be noted that, as used in the specification and the appended claims, the singular forms “a”, “an” and “the” include plural referents unless the context clearly dictates otherwise. Thus, for example, reference to “a material” may include mixtures of materials, reference to “a compound” may include multiple compounds, and the like. References cited herein are hereby incorporated by reference in their entirety, except to the extent that they conflict with teachings explicitly set forth in this specification.

In this specification and in the claims which follow, reference will be made to a number of terms which shall be defined to have the following meanings:

“Optional” or “optionally” means that the subsequently described circumstance may or may not occur, so that the description includes instances where the circumstance occurs and instances where it does not. For example, if a device optionally contains a feature for a barrier film, this means that the barrier film feature may or may not be present, and, thus, the description includes both structures wherein a device possesses the barrier film feature and structures wherein the barrier film feature is not present.

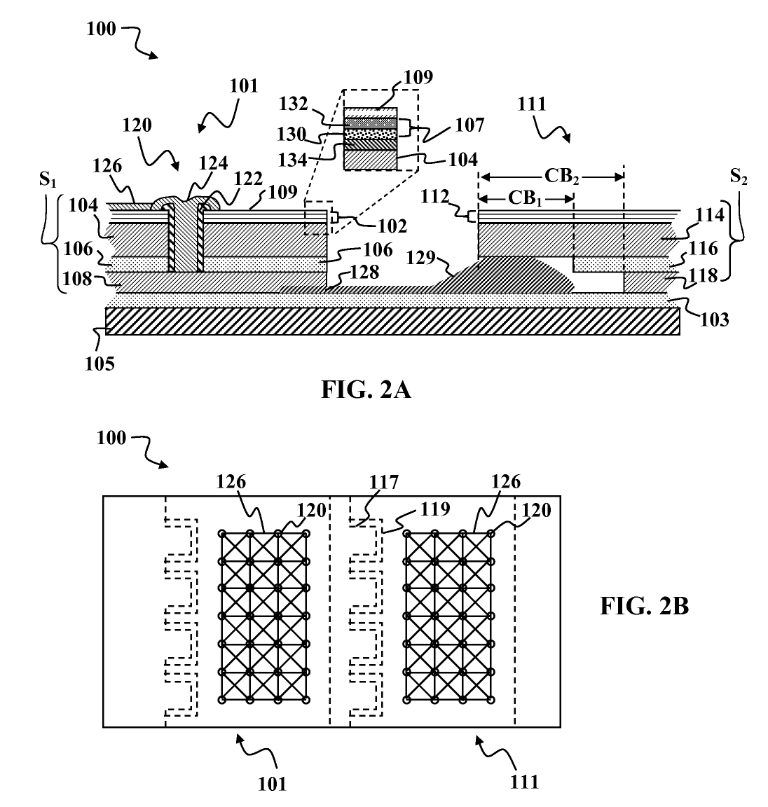

FIGS. 2A-2B illustrates an array 100 of optoelectronic devices according to an embodiment of the present invention. In some embodiments, this may be considered a series interconnections in an array 100 of optoelectronic devices. The array 100 includes a first device module 101 and a second device module 111. The device modules 101, 111 may be photovoltaic devices, such as solar cells, or light-emitting devices, such as light-emitting diodes. In a preferred embodiment, the device modules 101, 111 are solar cells. The first and second device modules 101, 111 are attached to an insulating carrier substrate 103, which may be made of a plastic material such as polyethylene terephthalate (PET), e.g., about 50 microns thick. The carrier substrate 103 may, in turn, be attached to a thicker structural membrane 105, e.g., made of a polymeric roofing membrane material such as thermoplastic polyolefin (TPO) or ethylene propylene diene monomer (EPDM), to facilitate installing the array 100 on an outdoor location such as a roof.

The device modules 101, 111, which may be about 4 inches in length and 12 inches wide, may be cut from a much longer sheet containing several layers that are laminated together. Each device module 101, 111 generally includes a device layer 102, 112 in contact with a bottom electrode 104, 114 and an insulating layer 106, 116 between the bottom electrode 104, 114 and a conductive back plane 108, 118. It should be understood that in some embodiments of the present invention, the back plane 108, 118 may be described as a backside top electrode 108, 118. The bottom electrodes 104, 114, insulating layers 106, 116 and back planes 108, 118 for substrates S₁, S₂ support the device layers 102, 112

In contrast to prior art cells, where the substrates are formed by depositing thin metal layers on an insulating substrate, embodiments of the present invention utilize substrates S₁, S₂ based on flexible bulk conducting materials, such as foils. Although bulk materials such as foils are thicker than prior art vacuum deposited metal layers they can also be cheaper, more readily available and easier to work with. Preferably, at least the bottom electrode 104, 114 is made of a metal foil, such as aluminum foil. Alternatively, copper, stainless steel, titanium, molybdenum or other suitable metal foils may be used. By way of example, the bottom electrodes 104, 114 and back planes 108, 118 may be made of aluminum foil about 1 micron to about 200 microns thick, preferably about 25 microns to about 100 microns thick; the insulating layers 106, 116 may be made of a plastic foil material, such as polyethylene terephthalate (PET) about 1 micron to about 200 microns thick, preferably about 10 microns to about 50 microns thick. In one embodiment, among others, the bottom electrode 104,114, insulating layer 106, 116 and back plane 108, 118 are laminated together to form the starting substrates S₁, S₂. Although foils may be used for both the bottom electrode 104, 114 and the back plane 108, 118 it is also possible to use a mesh grid on the back of the insulating layer 106, 116 as a back plane. Such a grid may be printed onto the back of the insulating layer 106, 116 using a conductive ink or paint. One example, among others, of a suitable conductive paint or ink is Dow Corning® PI-2000 Highly Conductive Silver Ink available from Dow Corning Corporation of Midland Mich. Dow Corning® is a registered trademark of Dow Corning Corporation of Midland Mich. Furthermore, the insulating layer 106, 116 may be formed by anodizing a surface of a foil used for the bottom electrode 104, 114 or back plane 108, 118 or both, or by applying an insulating coating by spraying, coating, or printing techniques known in the art.

The device layers 102, 112 generally include an active layer 107 disposed between a transparent conductive layer 109 and the bottom electrode 104. By way of example, the device layers 102, 112 may be about 2 microns thick. At least the first device 101 includes one or more electrical contacts 120 between the transparent conducting layer 109 and the back plane 108. The electrical contacts 120 are formed through the transparent conducting layer 109, the active layer 107, the bottom electrode 104 and the insulating layer 106. The electrical contacts 120 provide an electrically conductive path between the transparent conducting layer 109 and the back plane 108. The electrical contacts 120 are electrically isolated from the active layer 107, the bottom electrode 104 and the insulating layer 106.

The contacts 120 may each include a via formed through the active layer 107, the transparent conducting layer 109, the bottom electrode 104 and the insulating layer 106. Each via may be about 0.1 millimeters to about 1.5 millimeters, preferably 0.5 millimeters to about 1 millimeter in diameter. The vias may be formed by punching or by drilling, for example by mechanical, laser or electron beam drilling, or by a combination of these techniques. An insulating material 122 coats sidewalls of the via such that a channel is formed through the insulating material 122 to the back plane 108. The insulating material 122 may have a thickness between about 1 micron and about 200 microns, preferably between about 10 microns and about 200 microns.

The insulating material 122 should preferably be at least 10 microns thick to ensure complete coverage of the exposed conductive surfaces behind it. The insulating material 122 may be formed by a variety of printing techniques, including for example inkjet printing or dispensing through an annular nozzle. A plug 124 made of an electrically conductive material at least partially fills the channel and makes electrical contact between the transparent conducting layer 109 and the back plane 108. The electrically conductive material may similarly be printed. A suitable material and method, for example, is inkjet printing of solder (called “solderjet” by Microfab, Inc., Plano, Tex., which sells equipment useful for this purpose). Printing of conductive adhesive materials known in the art for electronics packaging may also be used, provided time is allowed subsequently for removal of solvent which may or may not be present, and curing. The plug 124 may have a diameter between about 5 microns and about 500 microns, preferably between about 25 and about 100 microns.

By way of nonlimiting example, in other embodiments, the device layers 102, 112 may be about 2 microns thick, the bottom electrodes 104, 114 may be made of aluminum foil about 100 microns thick; the insulating layers 106, 116 may be made of a plastic material, such as polyethylene terephthalate (PET) about 25 microns thick; and the backside top electrodes 108, 118 may be made of aluminum foil about 25 microns thick. The device layers 102, 112 may include an active layer 107 disposed between a transparent conductive layer 109 and the bottom electrode 104. In such an embodiment, at least the first device 101 includes one or more electrical contacts 120 between the transparent conducting layer 109 and the backside top electrode 108. The electrical contacts 120 are formed through the transparent conducting layer 109, the active layer 107, the bottom electrode 104 and the insulating layer 106, The electrical contacts 120 provide an electrically conductive path between the transparent conducting layer 109 and the backside top electrode 108. The electrical contacts 120 are electrically isolated from the active layer 107, the bottom electrode 104 and the insulating layer 106.

The formation of good contacts between the conductive plug 124 and the substrate 108 may be assisted by the use of other interface-forming techniques such as ultrasonic welding. An example of a useful technique is the formation of gold stud-bumps, as described for example by J. Jay Wimer in “3-D Chip Scale with Lead-Free Processes” in Semiconductor International, Oct. 1, 2003, which is incorporated herein by reference. Ordinary solders or conductive inks or adhesives may be printed on top of the stud bump.

In forming the vias, it is important to avoid making shorting connections between the top electrode 109 and the bottom electrode 104. Therefore, mechanical cutting techniques such as drilling or punching may be advantageously supplemented by laser ablative removal of a small volume of material near the lip of the via, a few microns deep and a few microns wide. Alternatively, a chemical etching process may be used to remove the transparent conductor over a diameter slightly greater than the via. The etching can be localized, e.g., by printing drops of etchant in the appropriate places using inkjet printing or stencil printing.

A further method for avoiding shorts involves deposition of a thin layer of insulating material on top of the active layer 107 prior to deposition of the transparent conducting layer 109. This insulating layer is preferably several microns thick, and may be in the range of 1 to 100 microns. Since it is deposited only over the area where a via is to be formed (and slightly beyond the borders of the via), its presence does not interfere with the operation of the optoelectronic device. In some embodiments of the present invention, the layer may be similar to structures described in U.S. patent application Ser. No. 10/810,072 to Karl Pichler, filed Mar. 25, 2004, which is hereby incorporated by reference. When a hole is drilled or punched through this structure, there is a layer of insulator between the transparent conducting layer 109 and the bottom electrode 104 which may be relatively thick compared to these layers and to the precision of mechanical cutting processes, so that no short can occur.

The material for this layer can be any convenient insulator, preferably one that can be digitally (e.g. inkjet) printed. Thermoplastic polymers such as Nylon PA6 (melting point (m.p.) 223° C.), acetal (m.p. 165° C.), PBT (structurally similar to PET but with a butyl group replacing the ethyl group) (m.p. 217° C.), and polypropylene (m.p. 165° C.), are examples which by no means exhaust the list of useful materials. These materials may also be used for the insulating layer 122. While inkjet printing is a desirable way to form the insulator islands, other methods of printing or deposition (including conventional photolithography) are also within the scope of the invention.

In forming the vias, it is useful to fabricate the optoelectronic device in at least two initially separate elements, with one comprised of the insulating layer 106, the bottom electrode 104 and the layers 102 above it, and the second comprised of the back plane 108. These two elements are then laminated together after the vias have been formed through the composite structure 106/104/102, but before the vias are filled. After this lamination and via formation, the back plane 108 is laminated to the composite, and the vias are filled as described above.

Although jet-printed solders or conductive adhesives comprise useful materials for forming the conductive via plug 124, it is also possible to form this plug by mechanical means. Thus, for example, a wire of suitable diameter may be placed in the via, forced into contact with the back plane 108, and cut off at the desired height to form the plug 124, in a manner analogous to the formation of gold stud bumps. Alternatively a pre-formed pin of this size can be placed into the hole by a robotic arm. Such pins or wires can be held in place, and their electrical connection to the substrate assisted or assured, by the printing of a very thin layer of conductive adhesive prior to placement of the pin. In this way the problem of long drying time for a thick plug of conductive adhesive is eliminated. The pin can have tips or serrations on it which punch slightly into the back plane 108, further assisting contact. Such pins may be provided with insulation already present, as in the case of insulated wire or coated wire (e.g. by vapor deposition or oxidation). They can be placed in the via before the application of the insulating material, making it easier to introduce this material.

If the pin is made of a suitably hard metal, and has a slightly tapered tip, it may be used to form the via during the punching step. Instead of using a punch or drill, the pin is inserted into the composite 106/104/102, to a depth such that the tip just penetrates the bottom; then when the substrate 108 is laminated to this composite, the tip penetrates slightly into it and forms a good contact. These pins may be injected into the unpunched substrate by, for example, mechanical pressure or air pressure directed through a tube into which the pin just fits.

One or more conductive traces 126, e.g., made of Al, Ni, or Ag, may be disposed on the transparent conducting layer 109 in electrical contact with the electrically conductive material 124. As shown in FIG. 2B, the traces 126 may interconnect multiple contacts 120 to reduce the overall sheet resistance. By way of example, the contacts 120 may be spaced about 1 centimeter apart from one another with the traces 126 connecting each contact with its nearest neighbor or in some cases to the transparent conductor surrounding it. Preferably, the number, width and spacing of the traces 126 is chosen such that the contacts 120 and traces 126 cover less than about 1% of the surface of the device module 101. The traces 126 may have a width between about 1 micron and about 200 microns, preferably between about 5 microns and about 50 microns. The traces 126 may be separated by center-to-center distances between about 0.1 millimeter and about 10 millimeters, preferably between about 0.5 millimeter and about 2 millimeters. Wider lines require a larger separation in order to avoid excessive shadowing loss. A variety of patterns or orientations for the traces 126 may be used so long as the lines are approximately equidistant from each other (e.g., to within a factor of two). An alternative pattern in which the traces 126 fan out from the contacts 120 is depicted in FIG. 2C. In another alternative pattern, shown in FIG. 2D, the traces 126 form a “watershed” pattern, in which thinner traces 126 branch out from thicker traces that radiate from the contacts 120. In yet another alternative pattern, shown in FIG. 2E, the traces 126 form a rectangular pattern from the contacts 120. It should be understood that in some embodiments of the present invention, the vertical lines may be thinner than the horizontal lines. The number of traces 126 connected to each contact may be more or less than the number shown in FIG. 2E. Some embodiments may have one more, two more, three more, or the like. The trace patterns depicted in the examples shown in FIG. 2B, FIG. 2C, FIG. 2D, and FIG. 2E are for the purpose of illustration and do not limit the possible trace patterns that may be used in embodiments of the present invention. Note that since the conductive back planes 108, 118 carry electrical current from one device module to the next the conductive traces 126 can include “fingers” while avoiding thick “busses”. This reduces the amount of shadowing due to the busses and also provides a more aesthetically pleasing appearance to the device array 100.

Fabricating the device modules 101, 111 on substrates S₁, S₂ made of relatively thick, highly conductive, flexible bulk conductor bottom electrodes 104, 114 and backplanes 108, 118 and forming insulated electrical contracts 120 through the transparent conducting layer 109, the active layer 130, the bottom electrodes 104, 114 and the insulating layer 106, 116 allows the device modules 101, 111 to be relatively large. Consequently the array 100 can be made of fewer device modules requiring fewer series interconnections compared to prior art arrays. For example, the device modules 101, 111 may be between about 1 centimeter and about 30 centimeters long and between about 1 and about 30 centimeters wide. Smaller cells (e.g., less than 1 centimeter long and/or 1 centimeter wide) may also be made as desired.

Note that since the back planes 108, 118 carry electric current from one device module to the next, the pattern of traces 126 need not contain thick busses, as used in the prior art for this purpose. Instead, the pattern of traces 126 need only provide sufficiently conductive “fingers” to carry current to the contacts 120. In the absence of busses, a greater portion of the active layers 102, 112 is exposed, which enhances efficiency. In addition, a pattern of traces 126 without busses can be more aesthetically pleasing.

Electrical contact between the back plane 108 of the first device module 101 and the bottom electrode 114 of the second device module 111 may be implemented by cutting back the back plane 118 and insulating layer 116 of the second device module to expose a portion of the bottom electrode 114. FIG. 2B illustrates an example of one way, among others, for cutting back the back plane 118 and insulating layer 116. Specifically, notches 117 may be formed in an edge of the insulating layer 116. The notches 117 align with similar, but slightly larger notches 119 in the back plane 118. The alignment of the notches 117, 119 exposes portions of the bottom electrode 114 of the second device module 111.

Electrical contact may be made between the back plane 108 of the first device module 101 and the exposed portion of the bottom electrode 114 of the second device module 111 in a number of different ways. For example, as shown in FIG. 2A, thin conducting layer 128 may be disposed over a portion of the carrier substrate 103 in a pattern that aligns with the notches 117, 119.

The thin conducting layer may be, e.g., a conductive (filled) polymer or silver ink. The conducting layer can be extremely thin, e.g., about 1 micron thick. A general criteria for determining the minimum thickness of the thin conducting layer 128 is that the fractional power p=(J/V)ρ(L₀²/d) dissipated in this layer is about 10⁻⁴ or less, where J is the current density, V is the voltage, L₀ is the length of the thin conductive layer 128 (roughly the width of the gap between the first and second device modules) and ρ and d are respectively the resistivity and the thickness of the thin conductive layer 128. In that case the loss of power from this source is far less than 1% of the power being generated, and is negligible. By way of numerical example, for many applications (J/V) is roughly 0.06 A/Vcm². If L₀=400 microns=0.04 cm then p is approximately equal to 10⁻⁴ (ρ/d). Thus, even if the resistivity ρ is about 10⁻⁵ Ωcm (which is about ten times less than for a good bulk conductor), ), the criterion can be satisfied with d less than about 1 micron (10⁻⁴ cm) thick. Thus, even a relatively resistive polymer conductor of almost any plausible printable thickness will work.

The first device module 101 may be attached to the carrier substrate 103 such that the back plane 108 makes electrical contact with the thin conducting layer 128 while leaving a portion of the thin conducting layer 128 exposed. Electrical contact may then be made between the exposed portion of the thin conducting layer 128 and the exposed portion of the bottom electrode 114 of the second device module 111. For example, a bump of conductive material 129 (e.g., more conductive adhesive) may be placed on the thin conducting layer 128 at a location aligned with the exposed portion of the bottom electrode 114. The bump of conductive material 129 is sufficiently tall as to make contact with the exposed portion of the bottom electrode 114 when the second device module 111 is attached to the carrier substrate. The dimensions of the notches 117, 119 may be chosen so that there is essentially no possibility that the thin conducting layer 128 will make undesired contact with the back plane 118 of the second device module 111. For example, the edge of the bottom electrode 114 may be cut back with respect to the insulating layer 116 by an amount of cutback CB₁ of about 400 microns. The back plane 118 may be cut back with respect to the insulating layer 116 by an amount CB₂ that is significantly larger than CB₁.

The device layers 102, 112 are preferably of a type that can be manufactured on a large scale, e.g., in a roll-to-roll processing system. There are a large number of different types of device architectures that may be used in the device layers 102, 112. By way of example, and without loss of generality, the inset in FIG. 2A shows the structure of a CIGS active layer 107 and associated layers in the device layer 102. By way of example, the active layer 107 may include an absorber layer 130 based on materials containing elements of groups IB, IIIA and VIA. Preferably, the absorber layer 130 includes copper (Cu) as the group IB, Gallium (Ga) and/or Indium (In) and/or Aluminum as group IIIA elements and Selenium (Se) and/or Sulfur (S) as group VIA elements. Examples of such materials (sometimes referred to as CIGS materials) are described in U.S. Pat. 6,268,014, issued to Eberspacher et al on Jul. 31, 2001, and US Patent Application Publication No. US 2004-0219730 A1 to Bulent Basol, published Nov. 4, 2004, both of which are incorporated herein by reference. A window layer 132 is typically used as a junction partner between the absorber layer 130 and the transparent conducting layer 109. By way of example, the window layer 132 may include cadmium sulfide (CdS), zinc sulfide (ZnS), or zinc selenide (ZnSe) or some combination of two or more of these. Layers of these materials may be deposited, e.g., by chemical bath deposition or chemical surface deposition, to a thickness of about 50 nm to about 100 nm. A contact layer 134 of a metal different from the bottom electrode may be disposed between the bottom electrode 104 and the absorber layer 130 to inhibit diffusion of metal from the bottom electrode 104. For example, if the bottom electrode 104 is made of aluminum, the contact layer 134 may be a layer of molybdenum.

Although CIGS solar cells are described for the purposes of example, those of skill in the art will recognize that embodiments of the series interconnection technique can be applied to almost any type of solar cell architecture. Examples of such solar cells include, but are not limited to: cells based on amorphous silicon, Graetzel cell architecture (in which an optically transparent film comprised of titanium dioxide particles a few nanometers in size is coated with a monolayer of charge transfer dye to sensitize the film for light harvesting), a nanostructured layer having an inorganic porous semiconductor template with pores filled by an organic semiconductor material (see e.g., US Patent Application Publication US 2005-0121068 A1, which is incorporated herein by reference), a polymer/blend cell architecture, organic dyes, and/or C₆₀ molecules, and/or other small molecules, micro-crystalline silicon cell architecture, randomly placed nanorods and/or tetrapods of inorganic materials dispersed in an organic matrix, quantum dot-based cells, or combinations of the above. Furthermore, embodiments of the series interconnection technique described herein can be used with optoelectronic devices other than solar cells.

Alternatively, the optoelectronic devices 101, 111 may be light emitting devices, such as organic light emitting diodes (OLEDs). Examples of OLEDs include light-emitting polymer (LEP) based devices. In such a case, the active layer 107 may include a layer of poly (3,4) ethylendioxythiophene : polystyrene sulfonate (PEDOT:PSS), which may be deposited to a thickness of typically between 50 and 200 nm on the bottom electrodes 104, 114, e.g., by web coating or the like, and baked to remove water. PEDOT:PSS is available from Bayer Corporation of Leverkusen, Germany. A polyfluorene based LEP may then be deposited on the PEDOT:PSS layer (e.g., by web coating) to a thickness of about 60-70 nm. Suitable polyfluorene-based LEPs are available from Dow Chemicals Company.

The transparent conductive layer 109 may be, e.g., a transparent conductive oxide (TCO) such as zinc oxide (ZnO) or aluminum doped zinc oxide (ZnO:Al), which can be deposited using any of a variety of means including but not limited to sputtering, evaporation, CBD, electroplating, CVD, PVD, ALD, and the like. Alternatively, the transparent conductive layer 109 may include a transparent conductive polymeric layer, e.g. a transparent layer of doped PEDOT (Poly-3,4-Ethylenedioxythiophene), which can be deposited using spin, dip, or spray coating, and the like. PSS:PEDOT is a doped, conducting polymer based on a heterocyclic thiophene ring bridged by a diether. A water dispersion of PEDOT doped with poly(styrenesulfonate) (PSS) is available from H.C. Starck of Newton, Mass. under the trade name of Baytron® P. Baytron® is a registered trademark of Bayer Aktiengesellschaft (hereinafter Bayer) of Leverkusen, Germany. In addition to its conductive properties, PSS:PEDOT can be used as a planarizing layer, which can improve device performance. A potential disadvantage in the use of PEDOT is the acidic character of typical coatings, which may serve as a source through which the PEDOT may chemically attack, react with, or otherwise degrade the other materials in the solar cell. Removal of acidic components in PEDOT may be carried out by anion exchange procedures. Non-acidic PEDOT can be purchased commercially. Alternatively, similar materials can be purchased from TDA materials of Wheat Ridge, Colo., e.g. Oligotron™ and Aedotron™.

The gap between the first device module 101 and the second device module 111 may be filled with a curable polymer, e.g epoxy or silicone. An optional encapsulant layer (not shown) may cover the array 100 to provide environmental resistance, e.g., protection against exposure to water or air. The encapsulant may also absorb UV-light to protect the underlying layers. Examples of suitable encapsulant materials include one or more layers of fluoropolymers such as THV (e.g. Dyneon's THV220 fluorinated terpolymer, a fluorothermoplastic polymer of tetrafluoroethylene, hexafluoropropylene and vinylidene fluoride), Tefzel® (DuPont), Tefdel, ethylene vinyl acetate (EVA), thermoplastics, polyimides, polyamides, nanolaminate composites of plastics and glasses (e.g. barrier films such as those described in commonly-assigned, co-pending U.S. Patent Application Publication US 2005-0095422 A1, to Brian Sager and Martin Roscheisen, entitled “INORGANIC/ORGANIC HYBRID NANOLAMINATE BARRIER FILM” which is incorporated herein by reference), and combinations of the above.

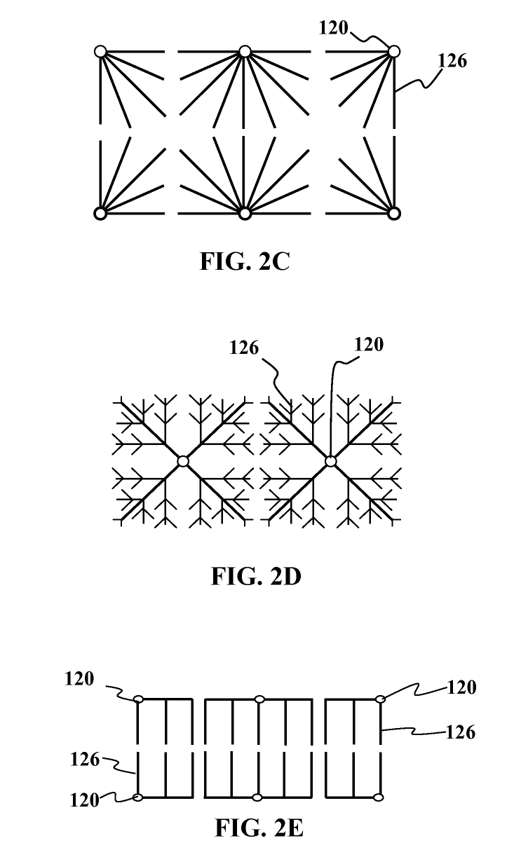

There are a number of different methods of fabricating interconnected devices according to embodiments of the present invention. For example, FIG. 3 illustrates one such method. In this method the devices are fabricated on a continuous device sheet 202 that includes an active layer between a bottom electrode and a transparent conductive layer, e.g., as described above with respect to FIGS. 2A-2B . The device sheet 202 is also patterned with contacts 203 like the contact 120 depicted in FIG. 2A. The contacts 203 may be electrically connected by conductive traces (not shown) as described above. An insulating layer 204 and a back plane 206 are also fabricated as continuous sheets. In the example shown in FIG. 3, the insulating layer 204 has been cut back, e.g., to form notches 205 that align with similar notches 207 in the back plane layer 206. The notches in the back plane layer 206 are larger than the notches in the insulating layer 204. The device sheet 202, insulating layer 204 and back plane layer are laminated together to form a laminate 208 having the insulating layer 204 between the device sheet 202 and the back plane 206. The laminate 208 is then cut into two or more device modules A,B along the dashed lines that intersect the notches 205, 207. A pattern of conductive adhesive 210 (e.g., a conductive polymer or silver ink) is then disposed on a carrier substrate 211. The modules are adhered to the carrier substrate 211. A larger area 212 of the conductive adhesive 210 makes electrical contact with the backplane 206 of module A. Fingers 214 of conductive adhesive 210 project out from the larger area 212. The fingers 214 align with the notches 205, 207 of module B. Extra conductive adhesive may be placed on the fingers 214 to facilitate electrical contact with the bottom electrode of module B through the notches 205, 207. Preferably, the fingers 214 are narrower than the notches 207 in the back plane 206 so that the conductive adhesive 210 does not make undesired electrical contact with the back plane 206 of module B.

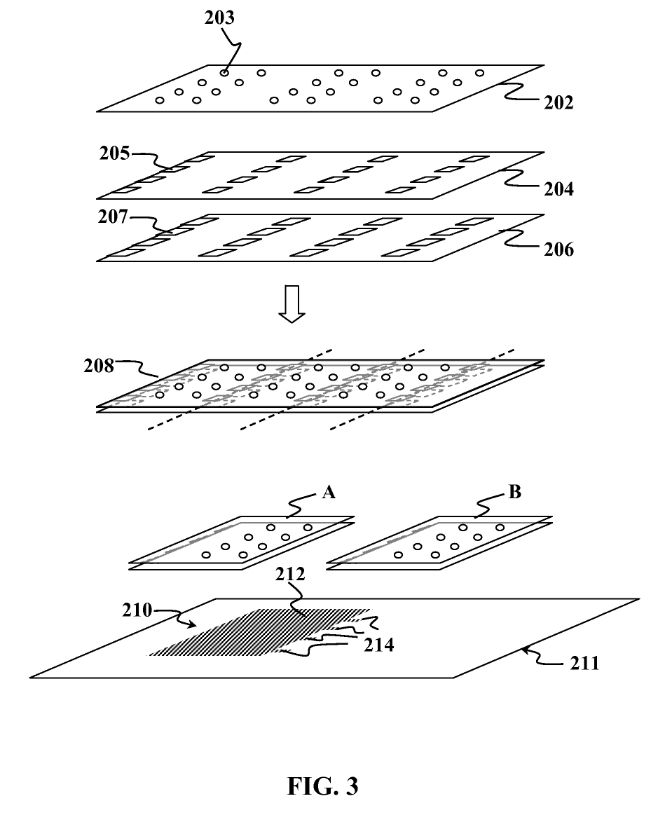

In the embodiment depicted in FIG. 3, the device sheet, insulating layer and back plane were laminated together before being cut into individual modules. In alternative embodiments, the layers may be cut first and then assembled into modules (e.g., by lamination). For example, as shown in FIG. 4, first and second device modules A′, B′ may be respectively laminated from pre-cut device layers 302A, 302B, insulating layers 304A, 304B, and back planes 306A, 306B. Each device layer 302A, 302B includes an active layer between a transparent conducting layer and a bottom electrode. At least one device layer 302A includes electrical contacts 303A (and optional conductive traces) of the type described above.

In this example, the back plane layer 306B of module B has been cut back by simply making it shorter than the insulating layer 304B so that the insulating layer 304B overhangs an edge of the back plane layer 306B. Similarly, the insulating layer 304B has been cut back by making it shorter than the device layer 302B or, more specifically, shorter than the bottom electrode of device layer 302B. After the pre-cut layers have been laminated together to form the modules A′, B′ the modules are attached to a carrier substrate 308 and electrical connection is made between the back plane 306A of module A′ and the bottom electrode of the device layer 302B of module B′. In the example shown in FIG. 4, the connection is made through a conductive adhesive 310 with a raised portion 312, which makes contact with the bottom electrode while avoiding undesired contact with the back plane 306B of module B′.

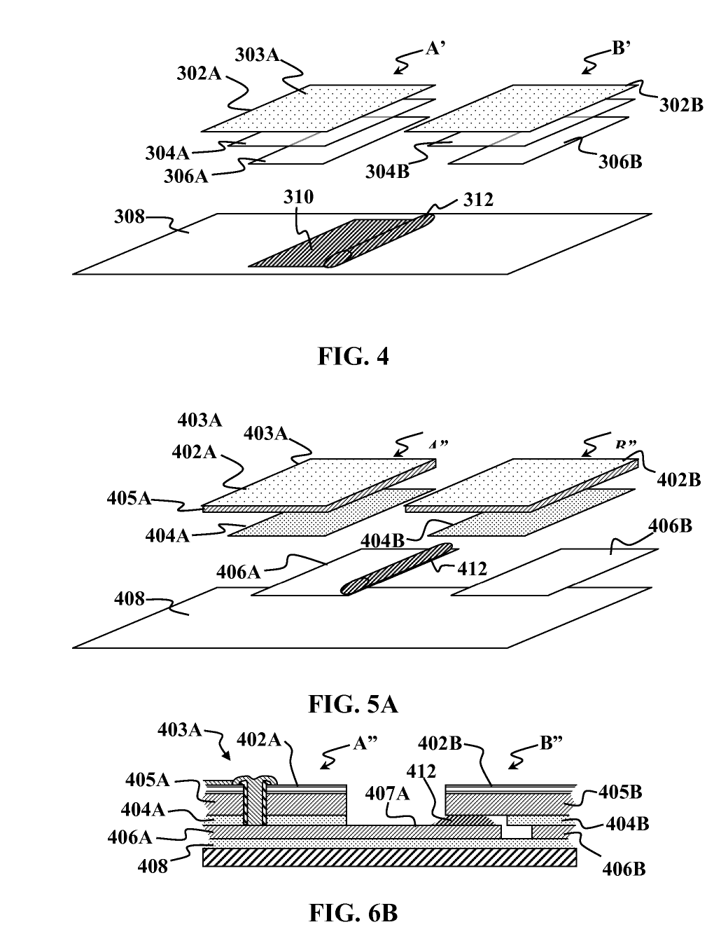

FIGS. 5A-5B depict a variation on the method depicted in FIG. 4 that reduces the use of conductive adhesive. First and second device modules A″, B″ are assembled from pre-cut device layers 402A, 402B, insulating layers 404A, 404B and back plane layers 406A, 406B and attached to a carrier substrate 408. Insulated electrical contacts 403A make electrical contact through the device layers 402A, a bottom electrode 405A and the insulating layer 406A as shown in FIG. 5B. Front edges of the insulating layer 404B and back plane 406B of module B″ are cut back with respect to the device layer 402B as described above with respect to FIG. 4. To facilitate electrical contact, however, a back edge of the back plane 406A of module A″ extends beyond the back edges of the device layer 402A and insulating layer 404A. As a result, the device layer 402B of module B″ overlaps the back plane 406A of module A″. A ridge of conductive adhesive 412 on an exposed portion 407A of the back plane 406A makes electrical contact with an exposed portion of a bottom electrode 405B of the device layer 402B as shown in FIG. 5B.

In preferred embodiments of the methods described above, individual modules may be fabricated, e.g., as described above, and then sorted for yield. For example, two or more device modules may be tested for one or more performance characteristics such as optoelectronic efficiency, open circuit voltage, short circuit current, fill factor, etc. Device modules that meet or exceed acceptance criteria for the performance characteristics may be used in an array, while those that fail to meet acceptance criteria may be discarded. Examples of acceptance criteria include threshold values or acceptable ranges for optoelectronic efficiency or open circuit voltage. By sorting the device modules individually and forming them into arrays, higher yields may be obtained than by fabricating arrays of devices monolithically.

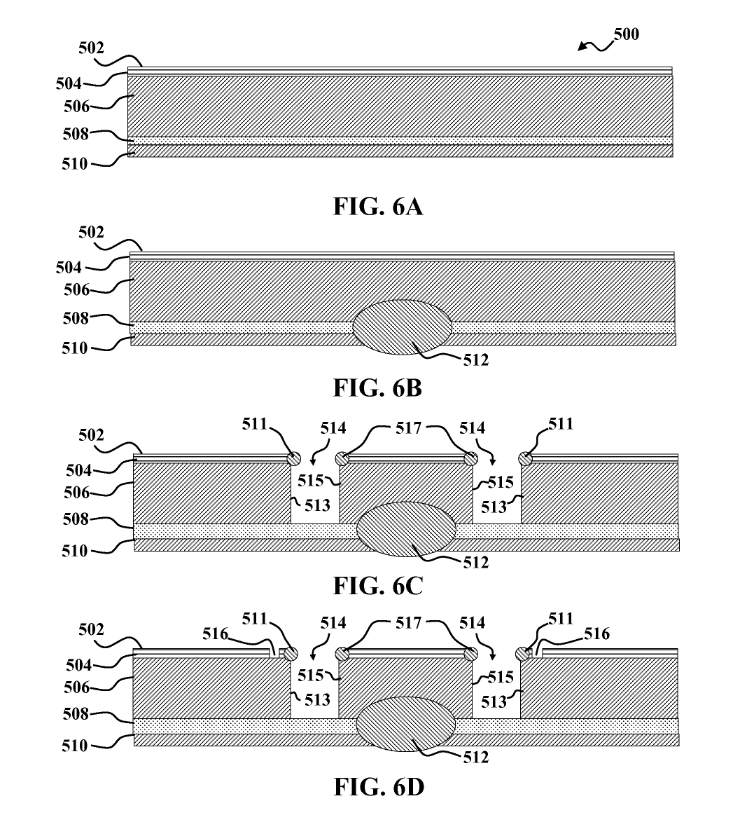

In the discussion of the electrical contacts 120 between the transparent conductive layer and the back plane, vias were formed, coated with an insulating material and filled with a conductive material. In an alternative embodiment, connection between the transparent conductive layer and the back plane may be effected using a portion of the bottom electrode as part of the electrical contact. FIGS. 6A-6H illustrate examples of how this may be implemented. Specifically, one may start with a structure 500 (as shown in FIG. 6A) with a transparent conducting layer 502 (e.g., Al:ZnO, i:ZnO), an active layer 504 (e.g., CIGS), a bottom electrode 506 (e.g., 100 um Al), an insulating layer 508 (e.g., 50 um PET), and a back plane 510 (e.g., 25 um Al). Preferably, the back plane 510 is in the form of a thin aluminum tape that is laminated to the bottom electrode 506 using an insulating adhesive as the insulating layer 508. This can greatly simplify manufacture and reduce materials costs.

Electrical connection 512 may be made between the bottom electrode 506 and the back plane at one or more locations as shown in FIG. 6B. For example, a spot weld may be formed through insulating layer 508, e.g., using laser welding. Such a process is attractive by virtue of making the electrical connection in a single step. Alternatively, the electrical connection 512 may be formed through a process of drilling a blind hole through the back plane 510 and the insulating layer 508 to the bottom electrode and filling the blind hole with an electrically conductive material such as a solder or conductive adhesive.

As shown in FIG. 6C, a trench 514 is then formed in a closed loop (e.g., a circle) around the electrical connection 512. The closed-loop trench 514 cuts through the transparent conducting layer 502, active layer 504, and bottom electrode 506, to the back plane 510. The trench 514 isolates a portion of the bottom electrode 506, active layer 504, and transparent conductive layer 502 from the rest of the structure 500. Techniques such as laser machining may be used to form the trench 514. If laser welding forms the electrical connection 512 with one laser beam and a second laser beam forms the trench 514, the two laser beams may be pre-aligned with respect to each other from opposite sides of the structure 500. With the two lasers pre-aligned, the electrical connection 512 and trench 514 may be formed in a single step, thereby enhancing the overall processing speed.

The process of forming the isolation trench may cause electrical short-circuits 511, 517 between the transparent conductive layer 502 and the bottom electrode 506. To electrically isolate undesirable short circuits 511 formed on an outside wall 513 of the trench 514 an isolation trench 516 is formed through the transparent conductive layer and the active layer to the bottom electrode 506 as shown in FIG. 6D. The isolation trench 516 surrounds the closed-loop trench 514 and electrically isolates the short circuits 511 on the outside wall 513 of the trench from the rest of the structure 500. A laser scribing process may form the isolation trench 516. A lesser thickness of material being scribed reduces the likelihood of undesired short circuits resulting from formation of the isolation trench 516.

Not all short circuits between the transparent conducting layer 502 and the bottom electrode 506 are undesirable. Electrical shorts 517 along an inside wall 515 of the trench 514 can provide part of a desired electrical path to the electrical connection 512. If a sufficient amount of desirable short circuiting is present, the electrical contact may be completed as depicted in FIG. 6E-6F. First an insulating material 518 is deposited into the closed-loop trench 514 and isolation trench 516 e.g., in a “donut” pattern with a hole in the middle as shown in FIG. 6E. Next electrically conductive fingers 520 are deposited over portions of the structure 500 including the isolated portion surrounded by the trench 514 and non-isolated portions as depicted in FIG. 6F. The insulating material 518 may be deposited in a way that provides a sufficiently planar surface suitable for forming the conductive fingers 520. Electrical contact is then made between the transparent conducting layer 502 in the non-isolated portions outside the trench 514 and the back plane 510 through the fingers 520, the transparent conducting layer within the isolated portion, electrical shorts 517 on the inside wall of the trench 514, the portion of the bottom electrode 506 inside the trench 514 and the electrical connection 512.

Alternatively, if the shorts 517 do not provide sufficient electrical contact, a process of drilling and filling may provide electrical contact between the fingers 520 and the isolated portion of the bottom electrode 506. In an alternative embodiment depicted in FIGS. 6G-6I, it is possible that insulating material 518′ covers the isolated portion when it is deposited as shown in FIG. 6G. The insulating material 518′ covering the isolated portion may be removed, e.g., by laser machining or mechanical processes such as drilling or punching, along with corresponding portions of the transparent conductive layer 502 and the active layer 504 to expose the bottom electrode 506 through an opening 519 as shown in FIG. 6H. Electrically conductive material 520′ forms conductive fingers, as described above. The electrically conductive material makes contact with the exposed bottom electrode 506 through the opening 519 and completes the desired electrical contact as shown in FIG. 6I.

Note that there are several variations on the techniques described above with respect to FIGS. 6A-6I. For example, in some embodiments it may be desirable to make the electrical connection 512 after the closed-loop trench has been formed and filled with insulating material. There are several advantages of the above-described process for forming the electrical contact. The process steps are simplified. It is easier to deposit the insulating layer without worrying about covering up the back plane. The process allows for a planar surface for depositing the fingers 520, 520′. Reliable electrical contact can be made between the bottom electrode 506 and the back plane 510 through laser welding. Furthermore, electrical shorts can be isolated without jeopardizing a 100% yield.

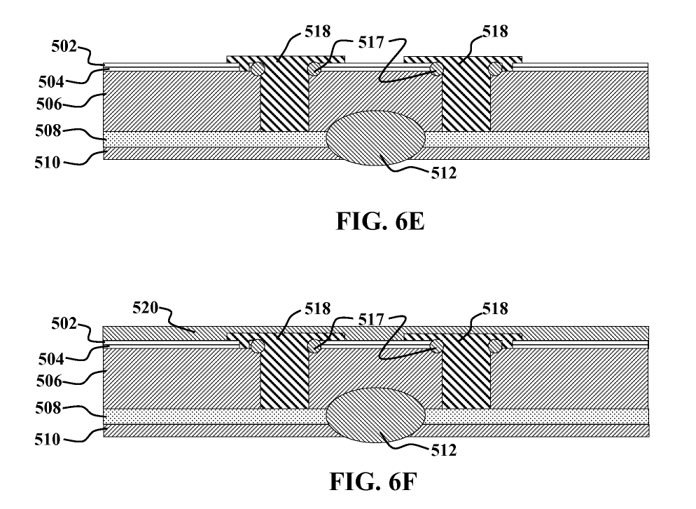

Referring now to FIG. 7, another aspect of the present invention will now be described. This embodiment of the present invention relates to the provision of low-cost structures and materials for photovoltaic cells which yield low shadowing and resistive losses from conductors facing the incoming sunlight, and which facilitate series interconnection.

Transparent conductor (TC) layers, particularly solution coated, traditionally have a level of resistivity that creates undesired electrical losses in a photovoltaic device. One known way to address this resistivity issue is to apply a thin conductive trace to the TC. The trace, which may be made of highly conductive metal having a resistivity, for example, in the vicinity of about 1−50×10−6 Ω·cm. In known devices using conventional traces, the area (shadowing) loss in such an optimized structure is about 11%, and the total is about loss 19% with a TC sheet resistance of 40 Ω/square. Unfortunately, even with printed traces, fingers, or grids, there is still loss of efficiency for two reasons. First, the fingers are opaque and so present a shadow to the photovoltaic material underneath. Second, the fingers have a finite resistance which leads to some power dissipation. These factors have an optimum, since minimizing shadowing implies narrower fingers, while minimizing resistance implies larger fingers. Furthermore, very small fingers tend to be impractical to fabricate because they require expensive techniques. Although the highest conductivity traces may be obtained from vacuum deposited metals, the method requires expensive deposition systems as well as patterning.

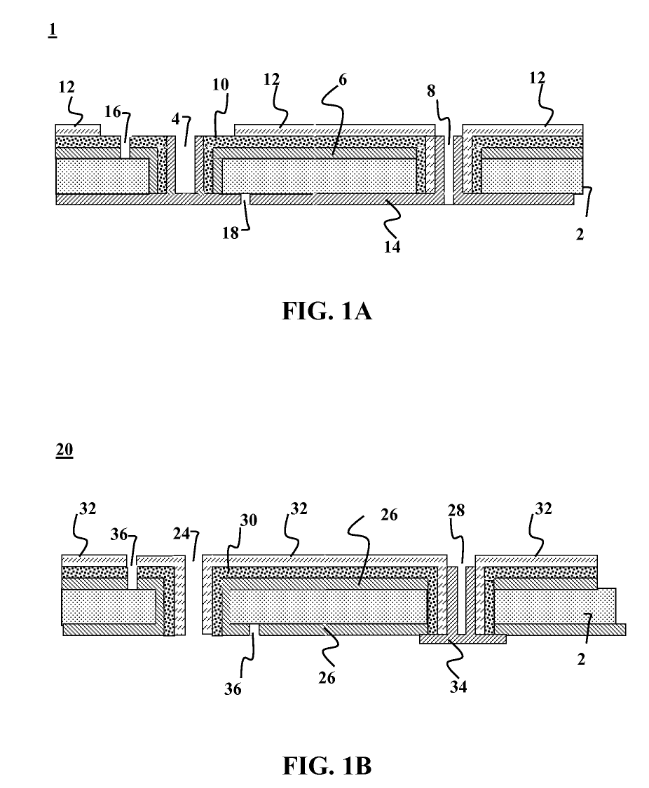

Referring now to FIGS. 1 and 7, although the structure of the present invention greatly reduces the conductivity requirement for the TC, it is advantageous to have even greater reductions, which may be achieved by the provision of fingers which are narrower (and hence less obstructive of light) than those conventionally used. By proper configuration of the size and shape of such fingers, traces, or grids, small losses on the order of about 10% or less can be achieved with a TC having sheet resistance of as large as about 200 Ω/sq., which is more than 10 times as large as required by conventional structures. In another embodiment, the total losses from finger shadowing and electrical resistance is about 5% or less. The ZnO or TC thickness may be reduced to ˜50−250 nm

Referring to FIG. 7, the traces 626 may interconnect multiple vias 620 of the EWT structure to reduce the overall sheet resistance. It should be understood that a variety of patterns or orientations for the traces 626 may be used as shown in FIG. 7 and as previously shown in FIGS. 2B-2D. By way of nonlimiting example, the vias 620 may be spaced about 1 centimeter apart from one another with the traces 626 connecting each contact with its nearest neighbor or in some cases to the transparent conductor surrounding it. The traces 626 may have a width between about 1 micron and about 200 microns, preferably between about 5 microns and about 50 microns. Wider lines imply a larger separation in order to avoid excessive shadowing loss.

Calculations show that for typical commercially available materials for traces such as but not limited to conductive epoxies with resistivities in the range of 1−10×10⁻⁵ Ω·cm, linewidth is a critical factor, and widths as small as about 25 microns are desirable, which leads to a shadowing loss of about 2.5% at 1 mm spacing. The vertical thickness of the lines may be about 1 to about 20 microns in height. In one embodiment of the present invention, the separation of lines is ideally in the vicinity of about 1 to about 2 mm, and the length about 0.5 mm. The sheet resistance of the traces may be below about 150 mΩ/square, and ideally not more than about 50 mΩ/square. Various combinations of width, spacing, length, thickness and resistivity of the traces around these values can be used to achieve comparably small total losses. As a nonlimiting example, in other embodiments with larger linewidths, the cross-sectional area of the fingers, traces, or grids are such that they achieve a total loss of about 10% or less. The overall cross-sectional area may reduce the electrical loss in a manner sufficient to compensate for loss related to increased shadowing from any increase in linewidth. In one embodiment, the cross-sectional area of the traces are sized so that the sheet resistances of the fingers is between about 150 mΩ/square and about 50 mΩ/square. In substantially all cases, the advantage of printing such traces is the large reduction in thickness and/or conductivity required from the transparent conductor, which thereby provides major reductions in both materials and fabrication equipment costs and optical % transmission losses from the transparent conductor.

In another embodiment of the present invention, to obtain 25 micron linewidths on properly prepared substrates, a variety of techniques such as but not limited to gravure printing may be used to provide the desired linewidth. Screen printing may also be used to provide line heights from about 5—about 25 microns or more, giving rise to a third dimension of variability in line width while maintaining conductivity. In one embodiment, the line height may be in the range of non-screen printed traces may be about 1 to about 10 microns. In another embodiment, the line height may be in the range of non-screen printed traces may be about 2 to about 6 microns. In yet another embodiment, the line height may be in the range of about 3 to about 5 microns. Because screen printing typically uses higher viscosity materials, it is capable of thicker deposits than other techniques, and when properly applied can provide narrow lines of width less than 50 microns.

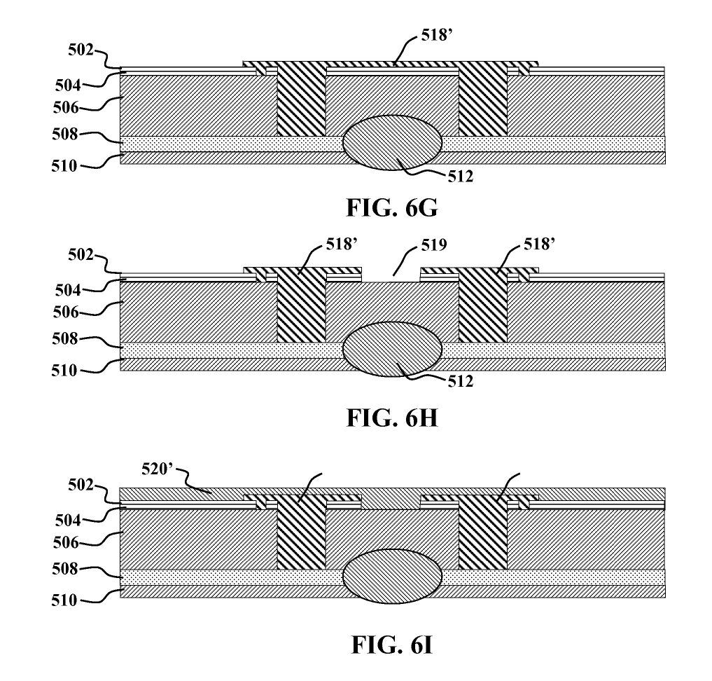

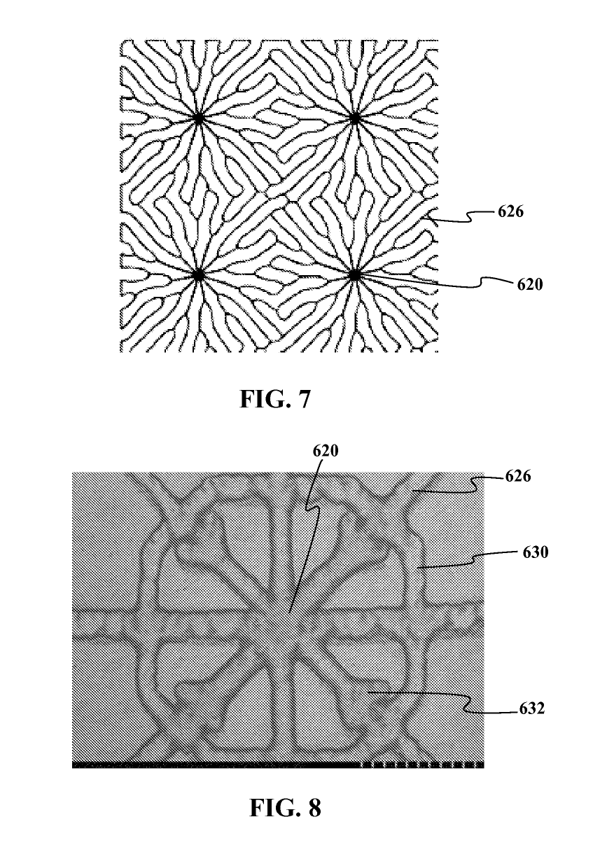

FIGS. 8 and 9 show other possible trace configurations. For example, FIG. 8 shows multiple intersecting traces 626 converging at a via 620. A hexagonal shaped trace 630 may also be used to intersect multiple traces 626 extending away from via 620. The linewidths may be in the ranges discussed above to achieve the desired. In one nonlimiting example, the lines may be sized to be a nominal width of about 60μm wide lines, but may be as wide as about 150—about 200 μm. Sheet resistance may be about 1 Ω/sq. The pattern may also include bumps 632 which have wider linewidths for certain sections of the traces 626. Optionally, some trace patterns may be without the bumps 632. FIG. 9 shows a pattern where a plurality of traces 626 radiate away from a via 620. It should be understood that embodiments of the invention using these patterns may have linewidths in the range of about 5 to about 50 microns. In another embodiment, linewidths may be between about 70 and about 110 microns; sheet resistance of about 50 mΩ/sq. Some embodiments may have linewidths between about 20 to about 30 microns to provide total losses of about 10% or less.

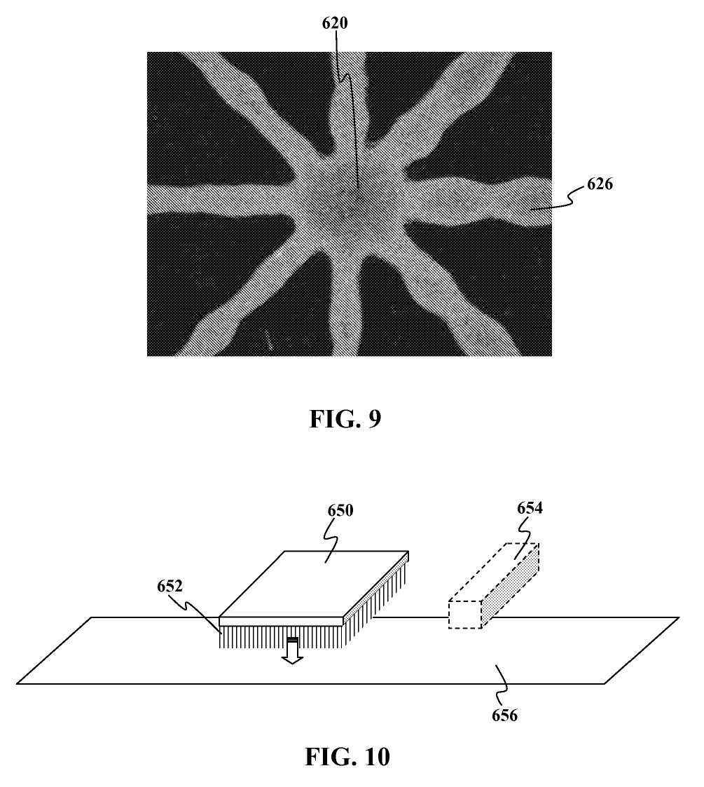

Referring now to FIG. 10, yet another embodiment of the present invention will now be described. It should be understood that to make the EWT solar cell configuration economically viable, a method of fabricating large numbers of small vias rapidly in the substrate is desired. A practical manufacturing line desires throughput on the order of several square meters per minute. It would be highly impractical to do this in silicon wafers. In embodiments of the present invention, vias may be advantageously formed at these speeds in metal foils of a few thousandths of an inch thickness by mechanical punching units which punch many vias simultaneously, or by laser ablation. FIG. 10 shows one embodiment of a punching device 650 for use with the present invention. It includes a punch device 650 that may include a plurality of penetrating members 652 to create a plurality of via holes simultaneously. In other embodiments, a laser device 654 (shown in phantom) may optionally be used to ablate a plurality of via holes in the substrate 656. Still further embodiments may include, but are not limited to, punch, laser, or other hole forming devices that create each via hole individually instead of in a simultaneous, batch process.

The top conductor of thin film solar cells is often composed of a doped form of ZnO, which is a relatively brittle material that when sheared by a punch breaks cleanly rather than deforming. If this or any other TC used deforms so that there is a significant probability of the formation of electrical contacts between the TC and the bottom conductor (which is only 1-2 microns vertical distance away), it is desirable to remove the TC before punching. This may be accomplished in the case of ZnO by a short exposure to mild acid, for example acetic acid (although other acids may also be used). The acid is printed by a droplet dispenser into holes in a polymer screen which is temporarily laminated to the top of the device foil and held by tension until the acid is removed by rinsing. This removal process is especially useful if the vias are formed by laser ablation, since laser heating tends to melt the ZnO and all surrounding materials at the same time, and can possibly cause shorts.

Although not limited to the following, while there exists a range of values of several of the parameters available for choice, it is desirable that the diameter of the vias should not exceed 1 mm, and should be preferably smaller. For example, if the diameter of the vias is 1 mm and the via spacing 10 mm, the fractional loss due to via area is 0.8%; at 0.5 mm diameter it is 0.2%. However, at 1.5 mm diameter the loss is 1.8%.

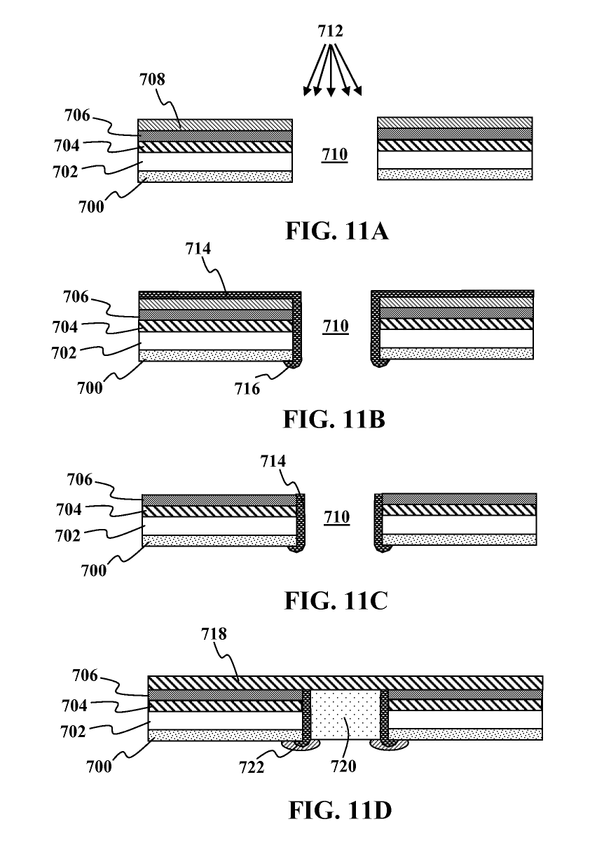

Referring now to FIGS. 11A-11D, yet another aspect of the present invention will now be described. FIG. 11A is a cross-sectional view showing a transparent conductor 700, a photovoltaic layer 702, a bottom electrode 704, insulating layer 706, and a liner 708. This device of FIG. 11A is an intermediate device with a via hole 710 that is not insulated. FIGS. 11A-11D show one method according to the present invention of insulating the via hole 710. As seen in FIG. 11A, the arrows 712 show the direction from which the insulating material will be sprayed. This spray may be applied using a variety of techniques including but not limited to an aerosol technique. The arrows 712 show that the spray is actually coming from an “underside” of the intermediate solar cell device. In this particle embodiment, the entire device has been flipped upside down to facilitate the spray process (i.e. the transparent conductor 700 is on the bottom of the stack). It should be understood that in other embodiments, the spray may come from the other direction or from both sides, sequentially or in combination. The spray of insulating material may also be applied without flipping the entire stack upside down in the manner shown in FIG. 11A. The insulating material may be EVA, PVOH, PVA, PVP, or another insulating material such as any thermoplastic polymer which has good adhesion to the metal foils 704 and 718. The EVA is preferably supplied as an emulsion of about 40-65% by weight in water. After application it is dried for about 90 seconds at 60-90 deg. with a Tg<150° C.

Referring now to FIG. 11B, the spray of insulating material as indicated by arrows 712 creates an insulating layer 714 that covers at least the side walls of the via hole 710. The insulating layer 714 may optionally be oversprayed to cover some portion of the transparent conductor 700 to ensure that the insulating layer fully insulates the sidewalls of the via hole 710. The overspray portion 716 may also improve adhesion of the insulating layer 714 to the stack of layers

FIG. 11C shows the liner 708 may be removed to remove the bottom layer of the insulating material 714. Optionally, it should be understood that the layer 708 may actually comprise of a plurality of discrete layers such as but not limited to a liner layer, an adhesive layer, and a liner layer. This may create a liner with better release qualities and/or adhesive qualities for the materials that they are in contact with. One liner material may interact better with one material than the other. This allows the liner to be optimized for the desired qualities. Still further, the layer 708 may have a plurality of discrete layers comprising of a liner layer, an adhesive layer, a PET or electrically insulating layer, an adhesive layer, and a liner layer configuration which guarantees election insulation by having the PET or electrically insulating layer.

FIG. 11D shows that with liner 708 removed, the backside electrode 718 may be applied to the underside of the stack. The stack is now cured in order to cause good adhesion of the backside electrode to the insulating layer. In the case of EVA, the cure takes place at about 150 C. for about 20 min. It should be understood that in some embodiments of the present invention, the backside electrode 718 may be a foil of material that covers the entire backside. The via hole 710 is filled with a conductive material 720 and fingers 722 are coupled to the conductive material 720.

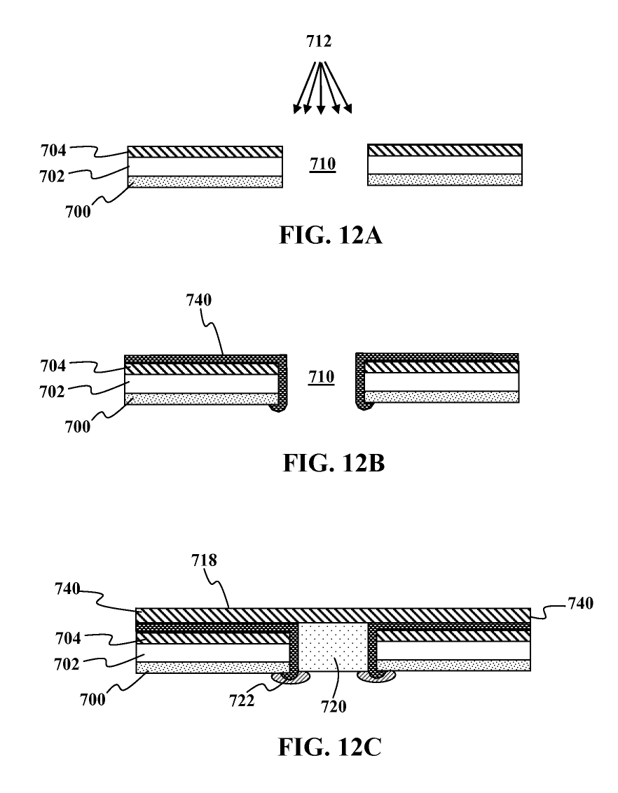

Referring now to FIGS. 12A-12C, yet another embodiment of the present invention will now be described. As seen in FIG. 12A, the stack of layers to be sprayed with insulating material does not include the liner 708 found previously in FIG. 11A. In the present embodiment, the insulating material also includes an adhesive quality. Hence, the insulating layer 740 when formed will not need to be removed from the underside and liner 708 is not needed, nor is insulating layer 706. Arrows 712 show that the insulating material may be sprayed on using an aerosol technique to cover the sidewalls of the via hole 710 and the underside of the layer 706.

FIG. 12B shows that the insulating layer 740 forms a layer covering the sidewall of the via hole 710 and along substantially the entire backside of layer 706. This simplifies the number of steps as there is no need to have a liner removal step or prior application of an insulating layer. The backside electrode layer 718 (FIG. 12C) may be applied directly to the layer 740.

FIG. 12C shows that once the backside electrode layer 718 may be applied and a conductive material 720 added to form an electrical connection via the traces 722 to coupled the transparent conductor layer 700 to the backside electrode 718 while being insulated from bottom electrode 704 by the insulating layer 740.

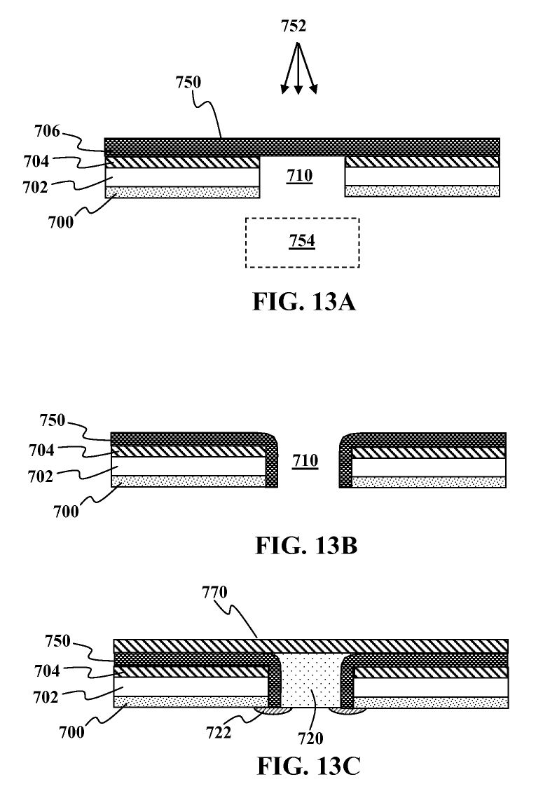

Referring now to FIGS. 13A-13B, a still further embodiment of the present invention will now be described. This embodiment of the invention describes another method of forming the insulating layer along the sidewalls of a via hole. As seen in FIG. 13A, a substantially uniform layer 750 of insulating material is formed along a backside of layer 106. Optionally, this layer 750 includes adhesive qualities to facilitate the attachment of the backside electrode layer 770. The layer 750 flows into the via and covers the side walls in a thickness comparable to its thickness on the bottom electrode 704. The exact thickness of the coating on the sidewall will depend to some extent on the aspect ratio of the via (the ratio of via diameter to foil thickness) as well as on the viscosity of the coating solution. In one embodiment, there is sufficient material to provide a layer between about 20 to about 100 microns thick along the wall of the via hole 710. It should be understood that some material from layer 750 may also fill part or all of the via hole 710. For ease of illustration, the layer 750 is depicted as extending over the via hole. A gas source as indicated by arrows 752 may be used to direct or flow the material from layer 750 into the via hole 710. Optionally, the source may blow gas, inert gas, or air. Still further, it should be understood that instead of blowing gas, a vacuum source 754 (shown in phantom) may be used instead or in combination with the gas source.

The layer 750 may be formed of sufficient thickness so that there is sufficient material to flow into the via and cover the side walls without being too thin and without filling the entire via hole. In one embodiment, the device may have a layer thickness in the range of about 50-100 microns. In another embodiment, the device may have a layer thickness in the range of about 50-100 microns. In another aspect, there is sufficient material in the layer 750 to coat the sidewalls of the via holes with insulating material about 20 to about 100 microns thick.

As seen in FIG. 13B, the via hole 710 remains open while the insulating layer 750 is formed by drawing the material towards the sidewalls in the via hole 710. The via hole 710 remains open to allow a conductive material 720 to be filled into the via hole 710. This method of printing a uniform layer may allow for a thicker layer of the insulating layer 750 to be formed along the walls of the via.

FIG. 13C shows that the backside electrode layer 770 may be coupled to the layer 750. The via hole 710 is filed with an insulating conductive material 720 and is coupled to fingers 722 which electrically couple the transparent conductor 700 to the backside electrode 770.

It should be understood of course that the methods using spraying and the methods using air impingement (via positive and/or negative pressure) are combinable in single or multiple steps. As a nonlimiting example, the spray-on application of insulating material may be subsequently treated by air impingement (via positive and/or negative pressure) to ensure that any material that may occlude a via hole from the spray on application are directed to coat the sidewalls of the via or to ensure that the sidewalls are fully coated. Optionally, in another nonlimiting example, insulating material applied using the uniform coating and air impingement technique may be supplemented with spraying insulating material onto at least the sidewalls of the via hole if the layer is not of a desired thickness. In yet another nonlimiting example, an initial layer of insulating material may be sprayed onto the sidewall of the via holes and then a uniform coating may be applied to using the air impingement technique to further thicken the insulating layer. In still other embodiments, two spray-on steps may be used to build up layer thickness. Another embodiment may use two coating steps (with air impingement after each coat) to build up the desired thickness.

While the invention has been described and illustrated with reference to certain particular embodiments thereof, those skilled in the art will appreciate that various adaptations, changes, modifications, substitutions, deletions, or additions of procedures and protocols may be made without departing from the spirit and scope of the invention. For example, with any of the above embodiments, the use of spray on insulating material may also be combined with other printing techniques to apply various layers of material to the solar cell. In one embodiment, insulation material may be provided by spray-on technique while the filing of the via may occur by printing, or vice versa.

Additionally, concentrations, amounts, and other numerical data may be presented herein in a range format. It is to be understood that such range format is used merely for convenience and brevity and should be interpreted flexibly to include not only the numerical values explicitly recited as the limits of the range, but also to include all the individual numerical values or sub-ranges encompassed within that range as if each numerical value and sub-range is explicitly recited. For example, a size range of about 1 nm to about 200 nm should be interpreted to include not only the explicitly recited limits of about 1 nm and about 200 nm, but also to include individual sizes such as 2 nm, 3 nm, 4 nm, and sub-ranges such as 10 nm to 50 nm, 20 nm to 100 nm, etc . . . .

The publications discussed or cited herein are provided solely for their disclosure prior to the filing date of the present application. Nothing herein is to be construed as an admission that the present invention is not entitled to antedate such publication by virtue of prior invention. Further, the dates of publication provided may be different from the actual publication dates which may need to be independently confirmed. All publications mentioned herein are incorporated herein by reference to disclose and describe the structures and/or methods in connection with which the publications are cited. For example, U.S. patent application Ser. No. 11/039,053, filed Jan. 20, 2005 and U.S. patent application Ser. No. 11/207,157 filed Aug. 16, 2005, are fully incorporated herein by reference for all purposes. U.S. patent application Ser. No. ______ (Attorney Docket No. NSL-060) filed on Apr. 4, 2006 is also fully incorporated herein by reference for all purposes.

While the above is a complete description of the preferred embodiment of the present invention, it is possible to use various alternatives, modifications and equivalents. Therefore, the scope of the present invention should be determined not with reference to the above description but should, instead, be determined with reference to the appended claims, along with their full scope of equivalents. Any feature, whether preferred or not, may be combined with any other feature, whether preferred or not. In the claims that follow, the indefinite article “A” or “An” refers to a quantity of one or more of the item following the article, except where expressly stated otherwise. The appended claims are not to be interpreted as including means-plus-function limitations, unless such a limitation is explicitly recited in a given claim using the phrase “means for.”

What is claimed is:

1. A device comprising:
a solar cell having a high efficiency backside electrode configuration, wherein the solar cell comprises of: at least one transparent conductor, a photovoltaic layer, at least one bottom electrode, and at least one backside electrode;
a plurality of electrical conduction fingers mounted to the transparent conductor in the solar cell;
a plurality of filled vias coupled to the electrical conduction fingers, wherein the filled vias extend through the at least one transparent conductor, the photovoltaic layer, and the at least one bottom electrode;
wherein the filled vias each have a conductive core that conducts charge from the transparent conductor to the backside electrode; and
a via insulating layer separating the conductive core in each via from the bottom electrode.

2. The device of claim 1 wherein the insulating layer is formed by aerosol coating of the via.

3. The device of claim 1 wherein the insulating layer is formed from an adhesive material.

4. The device of claim 1 wherein the backside conductor is electrically insulated from the bottom electrode and is connected by the filled vias which are spaced closely enough to each other such that the conductivity requirement of the top electrode is reduced and the need for area obscuring busbars is eliminated.

5. The device of claim 1 wherein the insulating layer is between about 20 to about 100 microns in thickness.

6. The device of claim 1 wherein the insulating layer comprises of at least one of the following materials: EVA, PVOH, PVA, PVP, or a thermoplastic polymer with a Tg less than about 150° C.

7. The device of claim 1 wherein the photovoltaic layer comprises of at least two discrete layers forming a P-N junction, wherein at least one of the layers comprises of a CIS-based material.

8. The device of claim 1 wherein filled vias have a diameter of about 1 mm or less.

9. The device of claim 1 wherein the insulating layer covers sidewalls of the vias and a portion of the transparent conductor around each of the vias, wherein the portion is within about 2 times the diameter of the via from the edge of the via.

10. A method comprising:
forming a solar cell comprising at least one transparent conductor, an photovoltaic layer, and at least one bottom electrode;
forming a plurality of via holes through the at least one transparent conductor, an photovoltaic layer, and at least one bottom electrode; and
coating the via holes to form an insulating layer along a side wall in each of the holes.

11. The method of claim 10 wherein coating comprises aerosol spraying a material that adheres to the side wall and forms the insulating layer.

12. The method of claim 10 wherein having a high efficiency backside electrode configuration.

13. The method of claim 10 further comprising:
filling each of the via holes with a conductive core that is electrically coupled to the transparent conductor and electrically insulated from the bottom electrode by the insulating layer in the via holes; and
forming a backside electrode coupled to the conductive core in substantially each of the via holes.

14. The method of claim 10 wherein coating comprises using a source that sprays insulating material from an underside of the solar cell to avoid substantially covering the transparent conductor with insulating material.

15. The method of claim 10 wherein coating comprises spraying an insulating material from an underside of the solar cell to minimize amount of material deposited on the transparent conductor without using a mask on the transparent conductor.

16. The method of claim 10 wherein coating comprises spraying an insulating material from a top side of the solar cell and using a mask on the transparent conductor to minimize the amount of material deposited on the transparent conductor.

17. The method of claim 10 wherein coating comprises spraying a sufficient amount of insulation to coat the side wall without completely filling the via holes.

18. The method of claim 10 wherein coating comprises spraying a sufficient amount of insulation to coat the side wall and to coat the underside of the bottom electrode to form a bottom insulation layer.

19. The method of claim 10 wherein the insulating layer is formed from an adhesive material.

20. The method of claim 10 wherein coating comprises forming an insulating layer by application of aerosol to the via holes.

21. The method of claim 10 wherein coating comprises forming an insulating layer by application of an insulating aerosol comprising of elements of a purely dielectric nature and an adhesive component.

22. The method of claim 10 wherein coating comprises spraying the via holes with insulating material and using gas impingement after spraying of the via holes to clear any via holes occluded by insulating material.

23. The method of claim 10 wherein coating comprises using gas impingement on a substantially uniform coating on one side of the solar cell to direct insulating material into each of the via holes.

24. The method of claim 10 wherein coating comprises forming an insulating layer in each of the vias by printing a substantially uniform coating of an insulating material on one side of the solar cell and using air impingement to direct the insulating material into each of the via holes and creating openings in the uniform coating corresponding to each of the via holes.

25. The method of claim 10 further comprising forming a plurality of electrical conduction fingers on the transparent conductor in the solar cell.

26. The method of claim 10 wherein coating comprises forming an insulating layer in each of the vias by printing a substantially uniform coating on one side of the solar cell and using suction on another side of the solar cell to pull insulating material of the uniform coating into each of the via holes and creating openings in the uniform coating corresponding to each of the via holes.
